(19) United States
(12) Patent Application Publication
(10) Pub. No.: US 2026/0252774 A1
(43) Pub. Date: Aug. 27, 2026

(54) AUTOMATED GENERATION OF COVERAGE DATA FOR CIRCUIT DESIGNS USING MACHINE LEARNING

(71) Applicant: Xilinx, Inc., San Jose, CA (US)

(72) Inventors: Vijay Palaparthy, Nagpur (IN); Prashant Nairmaley Joshi, Delhi (IN); Aasham Taneja, Jalandhar (IN); Tapodyuti Mandal, Hyderabad (IN); Ashif Khan Mohammed, Hyderabad (IN); Sridhar Rudraraju, Hyderabad (IN)

(73) Assignee: Xilinx, Inc., San Jose, CA (US)

(21) Appl. No.: 19/061,526

(22) Filed: Feb. 24, 2025

(51) Int. Cl. G06F 30/333; G06N 20/20

(52) U.S. Cl. CPC G06F 30/333; G06N 20/20

(57) ABSTRACT

Automated verification and generation of coverage data for a circuit design includes generating, by computer hardware, valid value ranges for coverpoint variables of a circuit design based on constraints for the coverpoint variables. A regression test is run on the circuit design using a verification testbench to generate test results and sampled values for the coverpoint variables. The sampled values of the coverpoint variables from the regression test are classified by a machine learning model based on the test results. Coverage data for the regression test is generated by the computer hardware by assigning the sampled values of the coverpoint variables to different ones of a plurality of bins based on the classifying.

### RESERVATION OF RIGHTS IN COPYRIGHTED MATERIAL

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

This disclosure relates to verification of circuit designs for integrated circuits (ICs) and, more particularly, to generation of coverage data for circuit designs for ICs using machine learning.

### BACKGROUND

Functional coverage is an important aspect of circuit design used by the semiconductor industry. Functional coverage ensures that when a circuit design, e.g., a register transfer level (RTL) design, is physically realized and released into the field, the circuit design functions as intended. Functional coverage provides a measure of the particular functions and/or features of the circuit design that have been exercised by tests. In this respect, functional coverage has become a necessary part of the development of every circuit design and/or integrated circuit. Functional coverage typically ensures rigorous review of circuit design testing to achieve 100% coverage.

Presently, functional coverage is a manual process as available electronic design automation (EDA) tools are unable to perform this task automatically. Designers must manually write/code functional coverage for their RTL designs. Because generating functional coverage requires a deep understanding of how constraints are written for variables in the RTL design, the design specification for the circuit design, and the workings of the particular interfaces used in the circuit design, the manual coding of functional coverage has required design engineers. With the increasing complexity of ICs, the complexity of manually coding functional coverage has increased in like manner thereby requiring even greater amounts of development time and expertise. The unavailability of functional coverage further adversely impacts turnaround time for reworking a given circuit design.

### SUMMARY

In one or more examples, a method includes generating, by computer hardware, valid value ranges for coverpoint variables of a circuit design based on constraints for the coverpoint variables. The method includes running a regression test on the circuit design using a verification testbench to generate test results and sampled values for the coverpoint variables. The method includes classifying, by a machine learning model, the sampled values of the coverpoint variables for the regression test based on the test results. The method includes generating, by the computer hardware, coverage data for the regression test by assigning the sampled values of the coverpoint variables to different ones of a plurality of bins based on the classifying.

In one or more examples, a computer system includes a hardware processor and one or more computer-readable storage mediums having program instructions stored thereon to cause the hardware processor to perform operations. The operations include generating valid value ranges for coverpoint variables of a circuit design based on constraints for the coverpoint variables. The operations include running a regression test on the circuit design using a verification testbench to generate test results and sampled values for the coverpoint variables. The operations include classifying, by a machine learning model, the sampled values of the coverpoint variables from the regression test based on the test results. The operations include generating coverage data for the regression test by assigning the sampled values of the coverpoint variables to different ones of a plurality of bins based on the classifying.

In one or more examples, a computer program product includes one or more computer-readable storage mediums having program instructions stored thereon. The program instructions are executable by computer hardware to cause the computer hardware to initiate operations. The operations include generating valid value ranges for coverpoint variables of a circuit design based on constraints for the coverpoint variables. The operations include running a regression test on the circuit design using a verification testbench to generate test results and sampled values for the coverpoint variables. The operations include classifying, by a machine learning model, the sampled values of the coverpoint variables from the regression test based on the test results. The operations include generating coverage data for the regression test by assigning the sampled values of the coverpoint variables to different ones of a plurality of bins based on the classifying.

This Summary section is provided merely to introduce certain concepts and not to identify any key or essential features of the claimed subject matter. Many other features and implementations of the disclosed technology will be apparent from the accompanying drawings and from the following detailed description.

### BRIEF DESCRIPTION OF THE DRAWINGS

The accompanying drawings show one or more implementations of the disclosed technology. The drawings, however, should not be construed to be limiting of the implementations to only the examples shown. Various aspects and advantages will become apparent upon review of the following detailed description and upon reference to the drawings.

FIG. 1 illustrates an example framework capable of automatically generating coverage data for circuit designs.

FIG. 2 is an example method of automated testing and generation of coverage data for a circuit design.

FIG. 3 is another example method of automated testing and generation of coverage data for a circuit design.

FIG. 4 illustrates an example of a constraint expression tree that may be generated by the framework of FIG. 1.

FIG. 5 illustrates an example of constraints applied to coverpoint variables in a circuit design and valid value ranges.

FIG. 6 illustrates an example of a machine learning model for use with the framework of FIG. 1.

FIG. 7 illustrates an example method of binning as performed by the framework of FIG. 1.

FIG. 8 illustrates an example of coverage data as automatically generated using the framework of FIG. 1.

FIG. 9 illustrates an example of a data processing system for use with the example implementations described herein.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to verification of circuit designs for integrated circuits (ICs) and, more particularly, to generation of coverage data for circuit designs for ICs using machine learning. In accordance with the implementations described within this disclosure, methods, systems, and computer-program products are provided that are capable of utilizing machine learning to automatically generate coverage data, such as functional coverage data, for a circuit design. Coverage data specifies how much and/or which portions of a given circuit design have been tested or exercised by regression testing.

In one or more implementations, a computer-based framework is provided that is capable of automatically generating code for functional coverage. The framework is capable of performing a variety of operations to facilitate automated functional coverage. For example, the framework is capable of extracting valid ranges for coverpoint variables that are specified in a verification testbench for a circuit design. Using a supervised machine learning paradigm, sampled values of the coverpoint variables obtained from regression testing may be classified based on test results. The framework is capable of automatically binning the sampled values of the coverpoint variables as classified resulting in the coverage data for the circuit design. The binning may be performed based, at least in part, on probabilities that are generated from the classification process for the different sampled values of the coverpoint variables.

The example implementations described herein are capable of achieving a bin classification in significantly less time than may be achieved through manual code generation. Further, the coverage data that is generated has a higher level of accuracy than data generated using other conventional techniques. The high level of accuracy and reduction in time required to generate the coverage data facilitates significantly faster convergence in reaching coverage goals for the circuit design.

Further, as the implementations may be applied to a variety of different circuit designs generally using a uniform approach, the resulting coverage data, e.g., different bins as generated, may be readily queried to detect particular errors in the circuit design itself and/or the verification testbench used for testing. That is, a standardized querying methodology may be implemented as the coverage data generated across different circuit designs may have a uniform formatting. The ability to query and the increased accuracy results in faster design closure and a higher quality-of-result in the resulting circuit design and the physical realization of the circuit design in and/or as an IC.

Further aspects of the disclosed technology are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

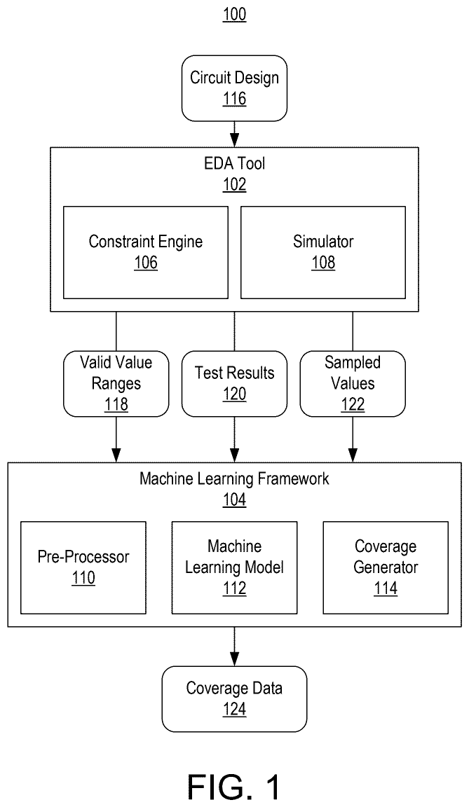

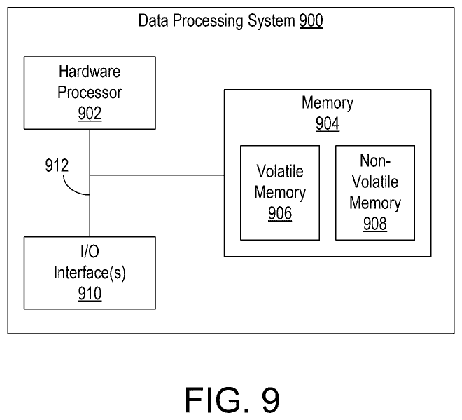

FIG. 1 illustrates an example of a framework 100 capable of automatically generating functional coverage for circuit designs. Framework 100 may be implemented as program instructions that may be executed by a data processing system or a plurality of interconnected, e.g., networked, data processing systems. An example of a data processing system that is capable of executing framework 100 is described in connection with FIG. 9.

In the example, framework 100 includes an electronic design automation (EDA) tool 102 and a machine learning (ML) framework 104. EDA tool 102 may include a constraint engine 106 and a simulator 108. ML framework 104 may include a pre-processor 110, a machine learning (ML) model 112, and a coverage generator 114.

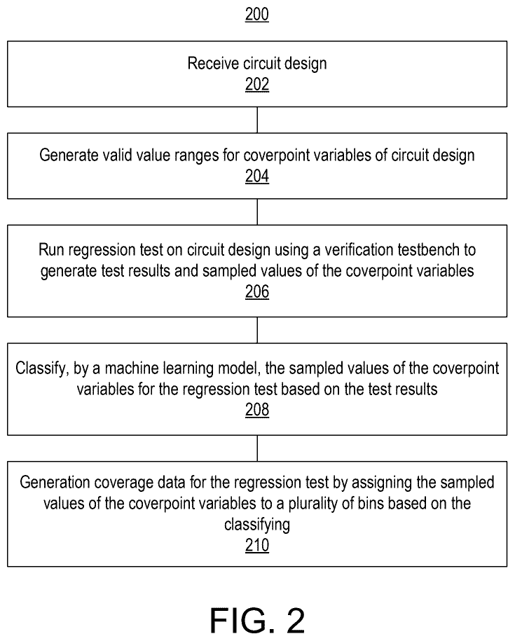

FIG. 2 is an example method 200 of automated testing and generation of coverage data for a circuit design. Method 200 may be performed by a data processing system executing framework 100 of FIG. 1. Referring to FIGS. 1 and 2 in combination, in block 202, EDA tool 102 receives a circuit design 116 for processing. Circuit design 116 may be specified as a register-transfer level (RTL) description. For example, circuit design 116 may be specified in a hardware description language.

In block 204, constraint engine 106 is capable of generating valid value ranges 118 for coverpoint variables of circuit design 116. A valid value range of a coverpoint variable specifies values of the coverpoint variable that are valid, or that may occur during testing and/or operation, given the constraints specified for the coverpoint variables. In this regard, valid value ranges 118 specify, for each of a plurality of coverpoint variables of circuit design 116, those values that each coverpoint variable may take on during a regression test (e.g., simulations).

In block 206, a regression test is run on circuit design 116. As an example, the regression test may involve one or more simulations executed by simulator 108. In one or more examples, simulator 108 may be implemented as an RTL simulator that implements a verification testbench in which circuit design 116 is the “device under test” or “DUT.” Appreciably, simulator 108 also may include components such as a stimulus generator (input driver), a response monitor (output monitor), a clock and reset generator, a comparator capable of comparing simulation output with expected results (scoreboard), and/or a control mechanism to manage the sequence or plurality of tests forming the regression test. The simulations performed by simulator 108 of circuit design 116 may be cycle-accurate simulations capable of providing or outputting sampled values on each clock cycle based on the simulation clock signal(s) provided by the clock generator.

The regression test may be executed. In running the regression test, simulator 108 is capable of supplying circuit design 116 with one or more input test vectors and capturing output from the regression test of circuit design 116. Based on the output captured from the regression test as compared with expected output, the verification testbench is capable of determining whether each individual test of the regression test of circuit design 116 passed or failed. Simulator 108 is capable of storing such data as test results 120. Further, simulator 108 is capable of capturing (e.g., sampling) the values taken on by the coverpoint variables (e.g., each coverpoint variable) for each test of the regression test and storing such data as sampled values 122.

In block 208, ML model 112 is capable of classifying the sampled values 122 of the coverpoint variables based on test results 120. In the example, ML framework 104 receives valid value ranges 118, test results 120, and sampled values 122 from EDA tool 102. Pre-processor 110 is capable of extracting the data items to be provided as input to ML model 112 and/or to coverage generator 114 from the data received from EDA tool 102. Pre-processor 110 is also capable of formatting extracted data into a format expected by ML model 112 and/or coverage generator 114. In block 208, ML model 112 is capable of classifying each sampled value 122 (of a coverpoint variable) of circuit design 116 by generating and outputting, for each sampled value 122, a probability that circuit design 116 passed the regression test.

In block 210, coverage generator 114 is capable of generating coverage data 124 for the regression test by assigning the sampled values of the coverpoint variables to a plurality of bins based on the classifying. For example, coverage generator 114 is capable of assigning each sampled value 122 to a selected bin. The selected bin is selected from a plurality of bins based on the classifying performed in block 208.

In one or more examples, the bin to which a given sampled value is assigned is selected based, at least in part, on an individual pass percentage of the sampled value (e.g., the probability of the sampled value from the classifying). In one or more examples, the bin to which a given sampled value is assigned is selected based, at least in part, on a cross of variable pass percentages (a cross of the probability of the sampled value of a coverpoint variable with one or more probabilities of sampled value(s) of one or more other coverpoint variables). In one or more examples, the bin to which a given sampled value is assigned is selected based, at least in part, on the probability of the sampled value and a cross of the sampled value with other sampled values (e.g., of other coverpoint variable as described).

Coverage data 124, as generated by coverage generator 114, is formed of the plurality of bins of the sampled values. In one or more examples, the plurality of class labels include valid, ignore, and illegal, but is not intended to be limited solely to the examples provided. As known, within circuit design 116, the coverpoint variables may be specified using a hardware description language such as SystemVerilog as standardized under IEEE-1800. Accordingly, in one or more examples, coverage data 124 may be formatted as covergoups/coverbins organized data as specified in IEEE-1800. For example, coverage data 124 may be specified as one or more files that comply with the requirements of IEEE-1800.

As generally known, a covergroup is a level of hierarchy in functional coverage functionality that may include one or more coverpoints (e.g., coverpoint variables). Each coverpoint variable may be associated with, or take on, a value from a value source in circuit design 116 such as a signal in an RTL design. Each coverpoint may include one or more bins that provide a count of the value(s) that the coverpoint variable takes on that meet with the particular requirements (e.g., value range(s) and/or value transitions) for that coverpoint variable during simulation and/or testing.

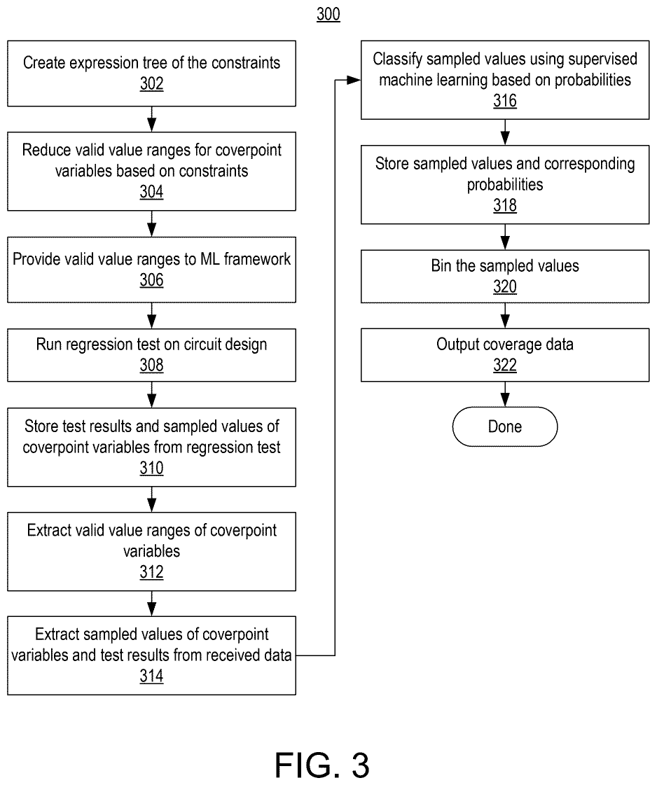

FIG. 3 is another example method 300 of automated testing and generation of coverage data for a circuit design. Method 300 presents a more detailed implementation than the example described in connection with FIG. 2. Method 300 may be performed by a data processing system executing framework 100 of FIG. 1 and may begin in a state where circuit design 116 has been received by framework 100.

In the example of FIG. 3, blocks 302 and 304 illustrate operations performed by constraint engine 106 in generating the valid value ranges for the coverpoint variables of circuit design 116. In block 302, constraint engine 106 is capable of creating a constraint expression tree. The constraint expression tree specifies the constraints of the coverpoint variables of circuit design 116 that may be specified (e.g., user-specified constraints). For example, constraint engine 106 is capable of extracting the constraints for each coverpoint variable of circuit design 116, if such constraint(s) are defined, and adding the constraints to the constraint expression tree.

In block 304, constraint engine 106 is capable of reducing the valid value ranges of the coverpoint variables of circuit design 116. In block 304, constraint engine 106 is capable of traversing the constraint expression tree once generated and enforcing the constraints on the respective coverpoint variables. In enforcing the constraints, constraint engine 106 is capable of detecting dependencies among the coverpoint variables and interaction between the corresponding constraints. For example, constraint engine 106 is capable of detecting that a coverpoint variable, based on a dependency of that coverpoint variable with another, will never take on a particular value despite that value being within a range defined by the constraints for the coverpoint variable. In this manner, constraint engine 106 is capable of reducing the valid value ranges of the coverpoint variables.

As an illustrative and non-limiting example, constraint engine 106 may traverse the constraint expression tree and detect the following constraints: var1 is constrained to be in the range of 0-10, var2 is constrained to be within the range of 1-10, and var3 is constrained to be less than 10. Further, var3 may be defined as the sum of var1 and var2. Example 1 illustrates pseudo code of a circuit design illustrating the conditions and constraints described.

```
class cls;
rand int var1; //range [−2147483648 to 2147483647]
rand int var2; //range [−2147483648 to 2147483647]
rand int var3; //range [−2147483648 to 2147483647]
constraint c {
  var1 inside {[0:10]};
  var2 inside {[0:10]};
  var3 < 10;
  var3 == (var1 + var2);
}
endclass
```

Based on this, constraint engine 106 is capable of detecting that despite the large potential range of values for var1, var2, and var3, var1 and var2 will be constraint to a range of 0 to 10. Further, var3 will be constrained to be less than 10. In traversing the constraint expression tree, constraint engine 106 is capable of detecting that neither var1 nor var2 may ever take on the value of 10. If either var1 or var2 would taken on the value of 10, despite the constraint for each permitting such values, the constraint on var3 would be violated. As such, constraint engine 106 is capable of reducing the valid value range for each of var1 and var2 to 1-9 in a first traversal. The range may be further reduced in subsequent traversals of the constraint expression tree.

In one or more examples, constraint engine 106 is capable of implementing a forward/backward implication on the constraint expression tree. In implementing the forward/backward implication, constraint engine 106 may continue to iterate over the constraint expression tree tracking the valid value range for each coverpoint variable in a data structure. Constraint engine 106 may continue to iterate over the constraint expression tree until no reduction of a valid value range for any coverpoint variable is achieved. The forward/backward implication is capable of testing combinations and/or exploring the available space of values in compliance with constraints to detect potential violations as described above with regard to var3 and update the constraint expression tree according to the results.

Example 2 below illustrates additional pseudo code illustrating variables that are defined and applicable constraints from an example circuit design.

### Example 2

```
class cls;
rand int var1; //range [−2147483648 to 2147483647]
rand int var2; //range [−2147483648 to 2147483647]
rand int var3; //range [−2147483648 to 2147483647]
rand int var4; //range [−2147483648 to 2147483647]
constraint c {
  var1 inside {[0:15]};
  var2 inside {[0:15]};
  var3 inside {[0:15]};
  var4 inside {[0:15]};
}
endclass
```

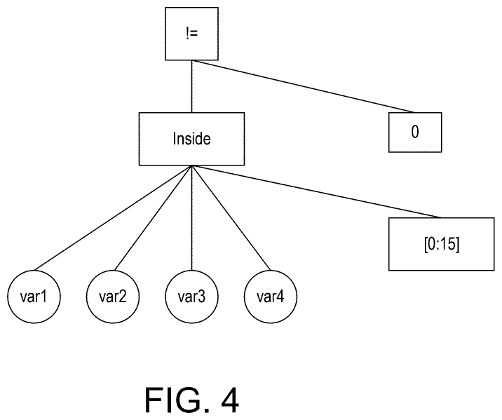

FIG. 4 illustrates an example of a constraint expression tree that may be generated by constraint engine 106 based on the pseudo code of Example 2. In the example of FIG. 4, the constraint expression tree specifies constraints for variables var1, var2, var3, and var 4. The constraint expression tree specifies that the values for each of var1, var2, var3, and var4 are to be within, e.g., “inside,” the defined range of 0 to 15.

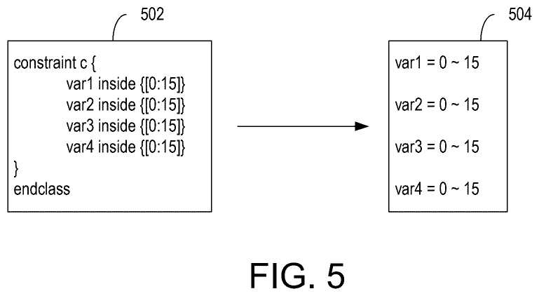

FIG. 5 illustrates an example of constraints applied to coverpoint variables in based on the example of FIG. 4 and valid value ranges. In the example, block 502 illustrates constraints for coverpoint variables that constraint engine 106 may detect for circuit design 116. The constraints of block 502 may be user-specified as part of the verification testbench for circuit design 116. Constraint engine 106 may extract the constraints from the verification testbench for circuit design 116. Block 504 illustrates the resulting valid value ranges for the coverpoint variables as may be generated by constraint engine 106 and described in connection with blocks 302 and 304 and in FIG. 4.

In block 306, EDA tool 102 is capable of providing valid value ranges 118 to ML framework 104. For example, the valid value ranges may be as specified in block 504 or further reduced/refined based on the forward/backward implication process implemented by constraint engine 106. In block 308, EDA tool 102, and more particularly simulator 108, is capable of running a regression test (e.g., simulations using the verification test bench) on circuit design 116. In running the regression test, simulator 108 is capable of obtaining results of the regression test indicating whether the test (e.g., each individual test of the regression test or suite) passed or failed. Further, simulator 108, in running the regression test, is capable of sampling the values of the coverpoint variables during the various simulations run. In block 310, simulator 108 is capable of storing test results 120 and sampled values 122 generated from the regression testing.

For purposes of illustration, consider the prior example in which circuit design 116 includes four coverpoint variables var1, var2, var3, and var4. The coverpoint variables may be System Verilog defined coverpoint variables. In this example, each coverpoint variable has a valid range from 0 to 15, which may be calculated by simulator 108 and provided to ML framework 104. In performing the regression test in block 308, sampled values are obtained for each of var1, var2, var3, and var4. Further, each constituent test of the regression test is passed (1) or failed (0).

Table 1 below illustrates an example of test results 120 and sampled values 122 as generated by the regression test performed by simulator 108.

TABLE 1

| | var1 | var2 | var3 | var4 | Output (Pass/Fail) |
|---|---|---|---|---|---|
| 1 | 3 | 7 | 8 | 5 | 0 |
| 2 | 2 | 11 | 6 | 4 | 1 |
| 3 | 2 | 4 | 6 | 9 | 1 |
| 4 | 2 | 4 | 7 | 9 | 0 |
| 5 | 1 | 7 | 4 | 10 | 1 |
| 6 | 11 | 11 | 6 | 4 | 0 |
| 7 | 2 | 4 | 6 | 1 | 1 |
| 8 | 7 | 4 | 14 | 9 | 0 |
| 9 | 8 | 5 | 6 | 3 | 1 |
| 10 | 2 | 11 | 6 | 5 | 0 |
| 11 | 2 | 4 | 6 | 9 | 0 |
| 12 | 1 | 2 | 3 | 4 | 0 |
| 13 | 5 | 4 | 8 | 4 | 1 |
| 14 | 5 | 7 | 4 | 11 | 1 |
| 15 | 5 | 2 | 6 | 8 | 1 |
| 16 | 3 | 4 | 11 | 6 | 0 |
| 17 | 3 | 15 | 8 | 3 | 0 |

In block 312, pre-processor 110 is capable of extracting the valid value ranges of the coverpoint variables as received from, or stored by, EDA tool 102. In block 314, pre-processor 110 is capable of extracting the sampled values 122 of coverpoint variables and the test results 120 from the data stored by simulator 108 from the regression test.

In block 316, sampled values 122 are classified by ML model 112 using a supervised machine learning technique. In one or more examples, ML model 112 implements an ensemble random forest supervised machine learning algorithm. ML model 112 is capable of generating, for each sampled value, a probability (Pr) based on the decision trees of ML model 112. For example, ML model 112 may include a plurality of decision trees that are part of the ensemble. The sample values may be processed through each tree to generate a classification result. The probability of each sampled value may be calculated by ML model 112 as an average of the predictions from the constituent decision trees.

Table 2 below illustrates example probabilities generated by ML model 112 for the sampled values of the coverpoint variables var1, var2, var3, and var4 from the data from Table 1. The probabilities illustrated in Table 2 are individual probabilities for each respective variable from different test runs of the regression test.

TABLE 2

| | Probability of | Probability of | Probability of | Probability of |
|---|---|---|---|---|
| | var1 | var2 | var3 | var4 |
| 1 | 0.96752381 | 0.5035 | 0.68298626 | 0.52562518 |
| 2 | 0.53467063 | 0.68672619 | 0.35588232 | 0.5087381 |
| 3 | 0.53467063 | 0.61978968 | 0.35588232 | 0.78615476 |
| 4 | 0.53467063 | 0.61978968 | 0.80901004 | 0.78615476 |
| 5 | 0.57099206 | 0.4035 | 0.18508333 | 0.33755952 |
| 6 | 0.64 | 0.68672619 | 0.35588232 | 0.5087381 |
| 7 | 0.53467063 | 0.61978968 | 0.35588232 | 0.13366667 |
| 8 | 0.68 | 0.61978968 | 0.95716667 | 0.78615476 |
| 9 | 0.23 | 0.18921248 | 0.35588232 | 0.4695 |
| 10 | 0.53467063 | 0.68672619 | 0.35588232 | 0.52562518 |
| 11 | 0.53467063 | 0.61978968 | 0.35588232 | 0.78615476 |
| 12 | 0.57099206 | 0.52088095 | 0.71508333 | 0.5087381 |
| 13 | 0.06 | 0.61978968 | 0.68298626 | 0.5087381 |
| 14 | 0.06 | 0.4035 | 0.18508333 | 0.15309127 |
| 15 | 0.06 | 0.52088095 | 0.35588232 | 0.30269841 |
| 16 | 0.96752381 | 0.61978968 | 0.86909524 | 0.8040974 |
| 17 | 0.96752381 | 0.88616667 | 0.68298626 | 0.4695 |

Referring to Tables 1 and 2, it may be observed that when var1 takes on a value of 5 or 8, the regression test is passed. As illustrated, the probability for var1=5 (rows 13, 14, 15) is low at Pr=0.06 and the probability for var1=8 (row 9) is low at Pr=0.23. By comparison, the probability for var1=3 (row 1, 16, 17) is high at Pr=0.96752381 as the regression test is always failed. In other cases, such as var1=2 (rows 2-4, 7, 10-11), Pr=0.53467063 as the test is passed in some cases and failed in others.

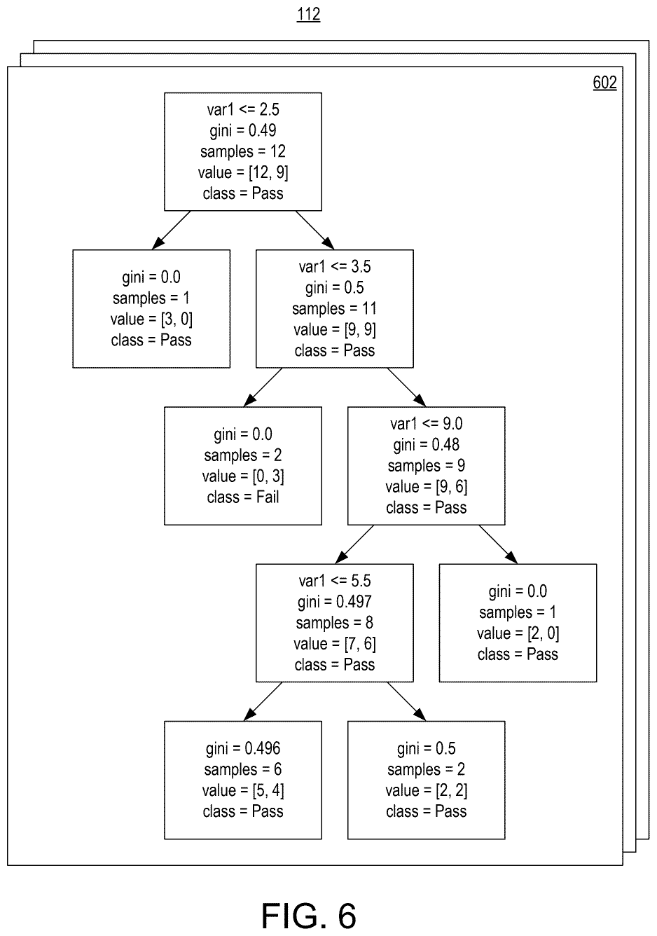

FIG. 6 is an example illustration ML model 112 in accordance with one or more implementations of the disclosed technology. In the example of FIG. 6, ML model 112 is implemented as a random forest model. The example decision tree 602 is illustrated as part of the ensemble random forest implementation. As generally known, a random forest model is an aggregation of multiple decision trees. Each decision tree includes a root node, decision nodes, and leaf nodes. The root node has all datasets. The collection of datasets may then be divided into leaf nodes of the decision tree. From the leaf nodes, the chunks of the datasets are also divided into leaf nodes (e.g., the leaf nodes are the last stage of the data sets division). The division/splitting criteria is based upon the Gini Impurity of the datasets in a given node. The Gini Index reflects how impure or mixed a particular dataset is (e.g., based on the splitting of the dataset for a given node of the decision tree). In this regard, the Gini Index may be used as an estimate of the likelihood of misclassifying a randomly selected item from the dataset. For example, the Gini Index=1−Sum (Individual Probability\hat{ }2 of each sample/dataset). In the Gini Index expression, the “individual probability” represents the probability of an individual or single variable also denoted as “Pr” herein. The decision tree calculates the probabilities of each/all variable and splits the datasets based upon the calculated Gini index into further branches (e.g., leaf nodes). The datasets may be split into subsequent nodes until a maximum node depth of the decision tree is reached or the Gini Index, also referred to as the Gini Impurity, is minimized.

In the example, ML model 112 may be run at the end of every regression test so that the probability for each sampled value of a coverpoint variable may be generated or updated based on new pass/fail test results from the regression test. Running ML model 112 at the end of each regression test rebuilds the ensemble of decision trees in a manner that is dependent on the results of the regression test. The updated probabilities for the coverpoint variables may be used to generate new or updated coverage data as the circuit design and/or verification testbench is modified.

In block 318, the sampled values and corresponding probabilities may be stored. In block 320, coverage generator 114 is capable of generating coverage data 124. Coverage data 124 may be specified as a file or other data structure. In one or more examples, coverage data 124 may specify covergroups and/or coverpoints (coverpoint variables). In general, the coverage data may be specified as a plurality of different bins, or categories, into which the sampled values are assigned based on the probabilities generated by ML model 112. The bins may be specified on a per coverpoint basis. In one or more implementations, coverage generator 114 may be implemented as a script that is capable of binning the sampled values. As an illustrative and nonlimiting example, the script may be implemented using Python, though the disclosed technology is not intended to be limited by the particular implementation of coverage generator 114 and/or the particular scripting language used.

For purposes of illustration, after execution of ML model 112, coverage generator 114 may be executed. Based on the probability of each sampled value of every coverpoint variable, coverage generator 114 is capable of creating coverages/coverbins. Coverage generator 114 is also capable of binning values of coverpoint variables that were specified in the valid range of values for the coverpoint variables but were not included or found within the data output from the regression test meaning that the value was not tested.

In block 322, coverage generator 114 is capable of outputting the coverage data. After block 322, circuit design 116 may be updated or modified to fix various errors (e.g., RTL errors) and/or fix various verification testbench errors. Once updated or modified, method 300 may be performed anew on the updated circuit design. As additional iterations of method 300 are performed, each iteration will include a larger number of passing tests as evidenced by the valid bin holding a greater number of entries (e.g., sampled values) while the ignore and/or illegal bins of the various coverpoint variable hold fewer entries. Using the example implementations described herein facilitates faster convergence as the binning performed is highly accurate.

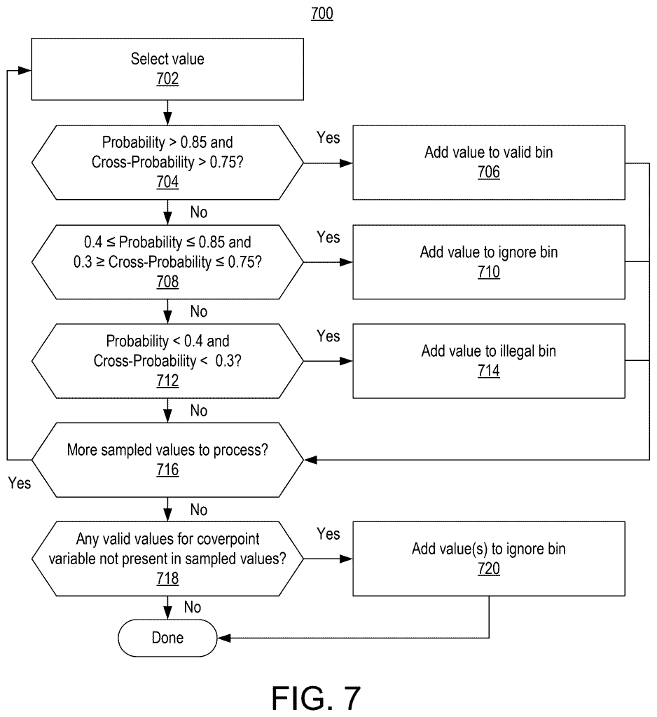

FIG. 7 illustrates an example method 700 of binning as performed by coverage generator 114 in accordance with one or more implementations of the disclosed technology. The example of FIG. 7 utilizes both individual probabilities and crosses of probabilities (e.g., cross-probabilities). Individual probabilities have been discussed. Crosses of probabilities may be calculated similar to individual probabilities. In the case of crosses of probabilities, the input is the combination of all the crosspoint variables (e.g., 4 crosspoint variables in the examples of FIGS. 4 and 5). The decision tree calculates the probabilities of all 4 variables as a combination and splits the datasets based upon the combined Gini Index into further branches (e.g., leaf nodes).

Table 3 illustrates an example of cross-probabilities calculated based on the expression Gini Impurity=1−Sum (P1\hat{ }2, P2\hat{ }2, P3\hat{ }2, P4\hat{ }2) of each sample/dataset. In this example, P* is the probability of the indicated crosspoint variable.

TABLE 3

| | CP Probability |
|---|---|
| 1 | 0.82883 |
| 2 | 0.538 |
| 3 | 0.538 |
| 4 | 0.538 |
| 5 | 0.538 |
| 6 | 0.44 |
| 7 | 0.53467063 |
| 8 | 0.44 |
| 9 | 0.839 |
| 10 | 0.602 |
| 11 | 0.602 |
| 12 | 0.602 |
| 13 | 0.93 |
| 14 | 0.93 |
| 15 | 0.93 |
| 16 | 0.82883 |
| 17 | 0.82883 |

In block 702, coverage generator 114 is capable of selecting a sampled value. In block 704, coverage generator 114 compares the probability (e.g., single probability or Pr) with a defined range of [0.85, 1] and a cross-probability with a defined range [0.75, 1]. In response to detecting that the probability is within the defined range (e.g., probability >0.85) and the cross probability is within the defined range (e.g., cross probability >0.75), coverage generator 114 adds the sampled value to the valid bin in block 706. A sampled value of a coverpoint variable with a probability and a cross-probability in these respective ranges means that the regression testing was passed for that value and combination of values (e.g., every time). After block 706, method 700 continues to block 716. In response to detecting that the probability and the cross-probability are not within the defined ranges, method 700 continues to block 708.

Continuing with block 708, coverage generator 114 compares the probability with a defined range of [0.4, 0.85] and the cross-probability with a defined range [0.3, 0.75]. In response to detecting that the probability is within the defined range (e.g., 0.4≤probability≤0.85) and the cross-probability is within the defined range (e.g., 0.3≤cross probability≤0.75), coverage generator 114 adds the sampled value to the ignore bin in block 710. A sampled value of a coverpoint variable with a probability and a cross-probability in these respective ranges means that the regression testing was passed and failed for that value and combination of values. After block 710, method 700 continues to block 716. In response to detecting that the probability and the cross-probability are not within the defined ranges, method 700 continues to block 712.

Continuing with block 712, coverage generator 114 compares the probability with a defined range of [0, 0.4] and the cross-probability with a defined range [0, 0.3]. In response to detecting that the probability is within the defined range (e.g., probability≤0.4) and the cross-probability is within the defined range (e.g., cross probability≤0.3), coverage generator 114 adds the sampled value to the illegal bin in block 714. A sampled value of a coverpoint variable with a probability and a cross-probability in these respective ranges means that the regression testing was failed for that sampled value and for the combination of sampled values (e.g., every time). After block 714, method 700 continues to block 716. In response to detecting that the probability and the cross probability are not within the defined ranges, method 700 also continues to block 716.

In block 716, coverage generator 114 determines whether there are any further sampled values from the regression test to process. In response to determining that one or more sampled values remain to be processed, method 700 loops back to block 702 to continue the binning process. In response to determining that no further sampled values remain to be processed, method 700 continues to block 718.

In block 718, coverage generator 114 is capable of detecting whether there are any valid values for any coverpoint variables that were not included in, e.g., are missing from, the sampled values obtained from the regression test. For example, coverage generator 114 is capable of comparing the sampled values for the different coverpoint variables with the valid values previously determined for the coverpoint variables to find matches and detect valid values not included in the sampled values. In response to detecting any valid values of coverpoint variables missing from the sampled values, coverage generator 114 adds such valid values to the ignore bin in block 720. After block 718 and/or 720, method 700 may end. Samples having a probability that is not placed into the legal or illegal bins (e.g., ranges) may be considered ignore values and placed in the ignore bins as the samples do not affect the pass or the fail condition for the regression test.

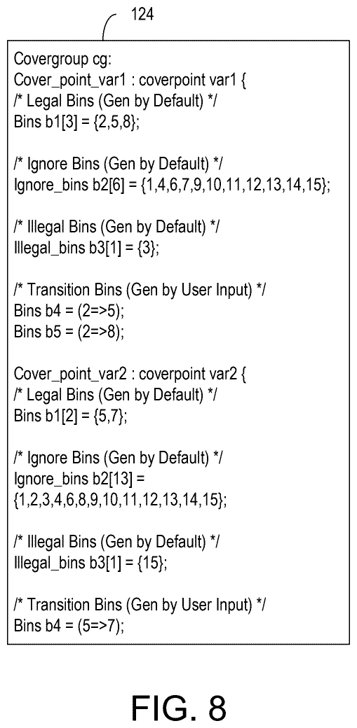

FIG. 8 illustrates an example of coverage data 124 as automatically generated in accordance with the example implementations described herein. In the example of FIG. 8, the transition bins may be implemented as user defined bins.

FIG. 9 illustrates an example of a data processing system 900. As used herein, “data processing system” refers to one or more hardware systems capable of processing data. Each hardware system may include one or more hardware processors and memory.

Data processing system 900 includes a hardware processor 902. Hardware processor 902 may be implemented as one or more hardware processors. Hardware processor 902 may be implemented as one or more circuits capable of executing computer-readable program instructions (program instructions). The circuit(s) may comprise integrated circuits (ICs) or may be embedded within an IC. In one or more examples, hardware processor 902 may be embodied as a central processing unit (CPU). Hardware processor 902 may include one or more cores, for example, where each core is capable of executing computer-readable program instructions. Hardware processor 902 may be implemented using any of a variety of architectures such as, for example, a complex instruction set computer architecture (CISC), a reduced instruction set computer architecture (RISC), a vector processing architecture, or other known architectures. For example, a hardware processor may be implemented using an x86 architecture (e.g., IA-32, IA-64), a Power Architecture, as an ARM processor, or the like.

Data processing system 900 can include memory 904. Memory 904 may be embodied as one or more computer-readable storage mediums. Memory 904 may include a volatile memory 906 and a non-volatile memory 908. Volatile memory 906 may be embodied as random-access memory (RAM) and may include cache memory. Volatile memory 906 may be referred to as “runtime memory.” Non-volatile memory 908 may include a non-volatile magnetic medium and/or a solid-state medium (typically called a “hard drive”). Non-volatile memory 908 also may include one or more disk drives capable of reading from and writing to various types of removable, non-volatile mediums such as a removable, non-volatile magnetic disk (e.g., a “floppy disk”) and/or a removable, non-volatile optical disk such as a CD-ROM, DVD-ROM or other optical media.

Memory 904 is capable of storing program instructions and/or data such that hardware processor 902 is capable of executing the program instructions to perform one or more operations as described within this disclosure. For example, the program instructions can include an operating system, one or more application programs, other program code, and program data that may be embodied as framework 100 of FIG. 1. Hardware processor 902, in executing the computer-readable program instructions, is capable of performing the various operations described herein that are attributable to a computer.

Data processing system 900 may include one or more Input/Output (I/O) interfaces 910. I/O interface(s) 910 allow data processing system 900 to communicate with one or more external devices and/or communicate over one or more networks such as a local area network (LAN), a wide area network (WAN), and/or a public network (e.g., the Internet). Examples of I/O interfaces 910 may include, but are not limited to, network cards, modems, network adapters (wired and/or wireless), hardware controllers, etc. Examples of external devices also may include devices that allow a user to interact with data processing system 900 (e.g., a display, a keyboard, and/or a pointing device) and/or other devices such as accelerator card.

Bus 912 represents one or more of any of a variety of communication bus structures. By way of example, and not limitation, bus 912 may be implemented as a Peripheral Component Interconnect Express (PCIe) bus. Bus 912 couples to each of hardware processor 902, memory 904, and I/O interface(s) 910 through respective interface circuitry thereby allowing the devices to communicate. Bus 912 may represent a plurality of buses that may be interconnected and/or hierarchically organized.

Data processing system 900 is only one example implementation. Data processing system 900 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

The example of FIG. 9 is not intended to suggest any limitation as to the scope of use or functionality of example implementations described herein. Data processing system 900 is an example of computer hardware that is capable of performing the various operations described within this disclosure. In this regard, data processing system 900 may include fewer components than shown or additional components not illustrated in FIG. 9 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

In one or more examples, EDA tool 102 is capable of performing an implementation flow on circuit design 116 (e.g., performing synthesis, placement, routing, and/or configuration data/bitstream generation). The resulting circuit design, as processed through the implementation flow may be physically realized in or as an IC. As discussed, the example implementations described herein facilitate faster convergence for circuit designs and greater quality-of-result (e.g., fewer errors and/or faults) in the physically realized IC.

The terminology used herein is for the purpose of describing particular examples only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “approximately” means nearly correct or exact, close in value or amount but not precise. For example, the term “approximately” may mean that the recited characteristic, parameter, or value is within a predetermined amount of the exact characteristic, parameter, or value.

As defined herein, the terms “at least one,” “one or more,” and “and/or,” are open-ended expressions that are both conjunctive and disjunctive in operation unless explicitly stated otherwise.

As defined herein, the term “automatically” and/or “automated” mean without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums.

A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “user” refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc., may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the implementations described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the implementations described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the implementations described herein.

Certain aspects of the implementations are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the implementations. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various implementations of the disclosed technology have been presented for purposes of illustration, but are not intended to be exhaustive or limited to the examples disclosed. Many modifications and variations will be apparent to those of ordinary skill in the art without departing from the scope and spirit of the described examples. The terminology used herein was chosen to best explain the principles of the examples, the practical application or technical improvement over technologies found in the marketplace, or to enable others of ordinary skill in the art to understand the examples disclosed herein.

What is claimed is:

1. A method, comprising:
generating, by computer hardware, valid value ranges for coverpoint variables of a circuit design based on constraints for the coverpoint variables;
running a regression test on the circuit design using a verification testbench to generate test results and sampled values for the coverpoint variables;
classifying, by a machine learning model, the sampled values of the coverpoint variables for the regression test based on the test results; and
generating, by the computer hardware, coverage data for the regression test by assigning the sampled values of the coverpoint variables to different ones of a plurality of bins based on the classifying.

2. The method of claim 1, further comprising:
comparing the valid value ranges for the coverpoint variables with the sampled values;
detecting missing valid values for one or more of the coverpoint variables based on the comparing; and
adding the missing valid values to a selected bin of the plurality of bins.

3. The method of claim 1, wherein the test results of the regression test whether the circuit design passed.

4. The method of claim 1, wherein the generating the valid value ranges comprises:
generating a constraint expression tree for the circuit design specifying constraints for the coverpoint variables; and
generating a valid value range of one or more of the coverpoint variables based on the constraints by performing a forward/backward implication on the constraint expression tree.

5. The method of claim 4, further comprising:
iteratively performing the forward/backward implication on the constraint expression tree until no valid value range of a coverpoint variable is reduced.

6. The method of claim 1, wherein the machine learning model is a random forest classifier, and wherein the classifying outputs probabilities that the circuit design passed the regression test for the sampled values of the coverpoint variables.

7. The method of claim 6, wherein the sampled values of the coverpoint variables are assigned to the plurality of bins based, at least in part, on the probabilities for the sampled values from the classifying.

8. The method of claim 7, wherein the sampled values of the coverpoint variables are assigned to the plurality of bins based, at least in part, on crosses of the probabilities.

9. The method of claim 1, wherein the plurality of bins include a valid bin, an ignore bin, and an illegal bin.

10. A computer system, comprising:
a hardware processor;
one or more computer-readable storage mediums having program instructions stored thereon to cause the hardware processor to perform operations comprising:
generating valid value ranges for coverpoint variables of a circuit design based on constraints for the coverpoint variables;
running a regression test on the circuit design using a verification testbench to generate test results and sampled values for the coverpoint variables;
classifying, by a machine learning model, the sampled values of the coverpoint variables from the regression test based on the test results; and
generating coverage data for the regression test by assigning the sampled values of the coverpoint variables to different ones of a plurality of bins based on the classifying.

11. The computer system of claim 10, wherein the operations further comprise:
comparing the valid value ranges for the coverpoint variables with the sampled values;
detecting missing valid values for one or more of the coverpoint variables based on the comparing; and
adding the missing valid values to a selected bin of the plurality of bins.

12. The computer system of claim 10, wherein the test results of the regression test whether the circuit design passed.

13. The computer system of claim 10, wherein the generating the valid value ranges comprises:
generating a constraint expression tree for the circuit design specifying constraints for the coverpoint variables; and
generating a valid value range of one or more of the coverpoint variables based on the constraints by performing a forward/backward implication on the constraint expression tree.

14. The computer system of claim 13, wherein the operations further comprise:
iteratively performing the forward/backward implication on the constraint expression tree until no valid value range of a coverpoint variable is reduced.

15. The computer system of claim 10, wherein the machine learning model is a random forest classifier, and wherein the classifying outputs probabilities that the circuit design passed the regression test for the sampled values of the coverpoint variables.

16. The computer system of claim 15, wherein the sampled values of the coverpoint variables are assigned to the plurality of bins based, at least in part, on the probabilities for the sampled values from the classifying.

17. The computer system of claim 16, wherein the sampled values of the coverpoint variables are assigned to the plurality of bins based, at least in part, on crosses of the probabilities.

18. The computer system of claim 10, wherein the plurality of bins include a valid bin, an ignore bin, and an illegal bin.

19. A computer program product comprising:
one or more computer-readable storage mediums having program instructions stored thereon, wherein the program instructions are executable by computer hardware to cause the computer hardware to initiate operations comprising:
generating valid value ranges for coverpoint variables of a circuit design based on constraints for the coverpoint variables;
running a regression test on the circuit design using a verification testbench to generate test results and sampled values for the coverpoint variables from the regression test;
classifying, by a machine learning model, the sampled values of the coverpoint variables for the regression test based on the test results; and
generating coverage data for the regression test by assigning the sampled values of the coverpoint variables to different ones of a plurality of bins based on the classifying.

20. The computer program product of claim 19, wherein the sampled values of the coverpoint variables are assigned to the plurality of bins based, at least in part, on probabilities for the sampled values generated by the classifying.
